(19) United States
(12) Patent Application Publication
(10) Pub. No.: US 2026/0305035 A1
(43) Pub. Date: Oct. 1, 2026

(54) DISPLAY PANEL, DISPLAY DEVICE, AND SIGNAL LINE REPAIRING METHOD

(71) Applicant: Tianma Advanced Display Technology Institute (Xiamen) Co.,Ltd., Xiamen (CN)

(72) Inventors: Yahua ZHANG, Xiamen (CN); Zhenyu JIA, Xiamen (CN); Wen YI, Xiamen (CN); Xiuli WANG, Xiamen (CN)

(21) Appl. No.: 19/259,960

(22) Filed: Jul. 3, 2025

(30) Foreign Application Priority Data
Mar. 25, 2025 (CN) 202510356365.6

(51) Int. Cl. H10H 29/49; H10H 29/01

(52) U.S. Cl. CPC H10H 29/49; H10H 29/012

(57) ABSTRACT

A display panel, a display device, and a signal line repairing method of a display panel are provided. The display panel includes: a substrate, a first power line layer, and a second power line layer. The first power line layer is located between the second power line layer and the substrate. The first power line layer and the second power line layer are insulated and overlap. The display panel has a short-circuit failure area and a non-short-circuit failure area, and the short-circuit failure area is provided with a first isolation groove and/or a second isolation groove. The first isolation groove insulates the first power line layer in the short-circuit failure area from the first power line layer in the non-short-circuit failure area. The second isolation groove insulates the second power line layer in the short-circuit failure area from the second power line layer in the non-short-circuit failure area.

### CROSS-REFERENCE TO RELATED APPLICATION

This application claims the priority of Chinese Patent Application No. 202510356365.6, filed on Mar. 25, 2025, the content of which is incorporated herein by reference in its entirety.

### TECHNICAL FIELD

The present disclosure generally relates to the field of display technology and, more particularly, relates to a display panel, a display device, and a signal line repairing method.

### BACKGROUND

For active drive display technology, it is necessary to design a power line on an entire surface of a display panel. A voltage of the power line plays a decisive role in many performances of the product, such as brightness, uniformity, and power consumption.

However, a surface of a current display panel is covered with a positive power signal line PVDD and a negative power signal line PVEE, and the positive power signal line PVDD and negative power signal line PVEE have a large overlapping area. The positive power signal line PVDD and negative power signal line PVEE are usually made of metal films such as TiAlTi and MoAlMo, and the two layers of films are isolated by films such as silicon nitride, silicon oxide, or planarization layers. However, during the preparation and transportation of the product, it is affected by foreign objects and external forces, and the isolation layer is easy to break the films, causing the positive power signal line PVDD and negative power signal line PVEE film layers to deform and conduct, thereby causing a short circuit problem. Once a short circuit occurs in a certain area, signals provided by the entire positive power signal line PVDD and the negative power signal line PVEE will be abnormal, which will lead to serious consequences such as product failure and burning.

### SUMMARY

One aspect of the present disclosure provides a display panel. The display panel includes: a substrate; and a first power line layer and a second power line layer located on the substrate. The first power line layer is located between the second power line layer and the substrate. The first power line layer and the second power line layer are insulated and overlap each other. The display panel has a short-circuit failure area and a non-short-circuit failure area, and the short-circuit failure area is provided with a first isolation groove and/or a second isolation groove. The first isolation groove insulates a portion of the first power line layer in the short-circuit failure area from another portion of the first power line layer in the non-short-circuit failure area. The second isolation groove insulates a portion of the second power line layer in the short-circuit failure area from another portion of the second power line layer in the non-short-circuit failure area.

Another aspect of the present disclosure provides a display device including a display panel. The display panel includes: a substrate; and a first power line layer and a second power line layer located on the substrate. The first power line layer is located between the second power line layer and the substrate. The first power line layer and the second power line layer are insulated and overlap each other. The display panel has a short-circuit failure area and a non-short-circuit failure area, and the short-circuit failure area is provided with a first isolation groove and/or a second isolation groove. The first isolation groove insulates a portion of the first power line layer in the short-circuit failure area from another portion of the first power line layer in the non-short-circuit failure area. The second isolation groove insulates a portion of the second power line layer in the short-circuit failure area from another portion of the second power line layer in the non-short-circuit failure area.

Another aspect of the present disclosure provides a signal line repairing method of a display panel. The method includes: determining a short circuit failure area of the display panel; and, removing part of the first power line layer in the short circuit failure area to form a first isolation groove; and/or, removing part of the second power line layer in the short circuit failure area to form a second isolation groove. The first power line layer is located between the second power line layer and a substrate. The first power line layer and the second power line layer are insulated and overlap with each other. The first isolation groove insulates a portion of the first power line layer in the short circuit failure area and another portion of the first power line layer in the non-short circuit failure area; and the second isolation groove insulates a portion of the second power line layer in the short circuit failure area and another portion of the second power line layer in the non-short circuit failure area.

Other aspects or embodiments of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a local top view of a first power line layer consistent with various disclosed embodiments in the present disclosure.

FIG. 2 illustrates a local top view of a second power line layer consistent with various disclosed embodiments in the present disclosure.

FIG. 3 illustrates a local top view of a first power line layer and a second power line layer after being stacked.

FIG. 4 illustrates a schematic diagram of a short circuit caused by foreign objects.

FIG. 5 illustrates a cross-sectional view of an exemplary display panel when a short circuit occurs between a first power line layer and a second power line layer consistent with various disclosed embodiments in the present disclosure.

FIG. 6 illustrates a cross-sectional view of an exemplary display panel after repairing consistent with various disclosed embodiments in the present disclosure.

FIG. 7 illustrates another cross-sectional view of an exemplary display panel after repairing consistent with various disclosed embodiments in the present disclosure.

FIG. 8 illustrates another cross-sectional view of an exemplary display panel after repairing consistent with various disclosed embodiments in the present disclosure.

FIG. 9 illustrates another cross-sectional view of an exemplary display panel after repairing consistent with various disclosed embodiments in the present disclosure.

FIG. 10 illustrates another cross-sectional view of an exemplary display panel after repairing consistent with various disclosed embodiments in the present disclosure.

FIG. 11 illustrates a cross-sectional view of another exemplary display panel consistent with various disclosed embodiments in the present disclosure.

FIG. 12 illustrates a cross-sectional view of another exemplary display panel consistent with various disclosed embodiments in the present disclosure.

FIG. 13 illustrates a local top view of another exemplary display panel consistent with various disclosed embodiments in the present disclosure.

FIG. 14 illustrates a cross-sectional view of the display panel along an AA′ direction in FIG. 13 consistent with various disclosed embodiments in the present disclosure.

FIG. 15 illustrates a local top view of another exemplary display panel consistent with various disclosed embodiments in the present disclosure.

FIG. 16 illustrates a cross-sectional view of the display panel along a BB′ direction in FIG. 15.

FIG. 17 illustrates a positional relationship of an isolation groove and a light-emitting device arrangement area of an exemplary display panel consistent with various disclosed embodiments in the present disclosure.

FIG. 18 illustrates a local top view of an exemplary second power line layer consistent with various disclosed embodiments in the present disclosure.

FIG. 19 illustrates a cross-sectional view along a CC′ direction in FIG. 18 consistent with various disclosed embodiments in the present disclosure.

FIG. 20 illustrates a local top view of an exemplary second power line layer consistent with various disclosed embodiments in the present disclosure.

FIG. 21 illustrates a local top view of an exemplary first power line layer consistent with various disclosed embodiments in the present disclosure.

FIG. 22 illustrates an exemplary pixel circuit consistent with various disclosed embodiments in the present disclosure.

FIG. 23 illustrates an exemplary display device consistent with various disclosed embodiments in the present disclosure.

FIG. 24 illustrates an exemplary signal line repairing method of a display panel consistent with various disclosed embodiments in the present disclosure.

### DETAILED DESCRIPTION

Reference will now be made in detail to exemplary embodiments of the disclosure, which are illustrated in the accompanying drawings. Hereinafter, embodiments consistent with the disclosure will be described with reference to drawings. In the drawings, the shape and size may be exaggerated, distorted, or simplified for clarity. Wherever possible, the same reference numbers will be used throughout the drawings to refer to the same or like parts, and a detailed description thereof may be omitted. Further, in the present disclosure, the disclosed embodiments and the features of the disclosed embodiments may be combined under conditions without conflicts. It is apparent that the embodiments described are some but not all of the embodiments of the present disclosure. Based on the disclosed embodiments, those ordinarily skilled in the art may derive other embodiments consistent with the present disclosure, all of which are within the scope of the present disclosure.

Moreover, the present disclosure is described with reference to schematic diagrams. For the convenience of descriptions of the embodiments, the cross-sectional views illustrating the device structures may not follow the common proportion and may be partially exaggerated. Besides, those schematic diagrams are merely examples, and not intended to limit the scope of the disclosure. Furthermore, a three-dimensional (3D) size including length, width, and depth should be considered during practical fabrication.

In the present disclosure, terms such as “center”, “longitudinal”, “lateral”, “length”, “width”, “thickness”, “up”, “down”, “front”, “back”, “left”, “right”, “vertical”, “horizontal”, “top”, “bottom”, “inside”, “outside”, “clockwise”, “counterclockwise”, “axial”, “radial”, “circumferential”, etc., indicate orientations or positional relationships based on the orientations or positional relationships shown in the accompanying drawings, and are only for the convenience of describing the present disclosure and simplifying the description, and do not indicate or imply that the device or element referred to must have a specific orientation, be constructed and operated in a specific orientation, and therefore should not be understood as limiting the present disclosure.

In the present disclosure, relational terms such as first and second are only used to distinguish one entity or operation from another entity or operation, and do not necessarily require or imply any actual relationship between these entities or operations or order. Moreover, the terms “including”, “comprising” or any other variants thereof are intended to cover non-exclusive inclusion, such that a process, method, article, or device that includes a series of elements includes not only those elements, but also those that are not explicitly listed or also include elements inherent to this process, method, article or equipment. If there are no more restrictions, the elements defined by the sentence “including . . . ” do not exclude the existence of other same elements in the process, method, article, or equipment that includes the elements.

It should be understood that when describing the structure of a component, when a layer or region is referred to as being “on” or “above” another layer or another region, the layer or region may be directly on the other layer or region, or indirectly on the other layer or region, for example, layers/components between the layer or region and another layer or another region. And, for example, when the component is reversed, the layer or region may be “below” or “under” the other layer or region. In the present disclosure, the term “electrical connection” refers to that two components are directly electrically connected with each other, or the two components are electrically connected via one or more other components.

In the present disclosure, unless otherwise clearly specified and limited, the terms “installed”, “connected”, “fixed” and the like appear, should be understood in a broad sense. For example, it can be a fixed connection, a detachable connection, or an integrated connection; it can be a mechanical connection or an electrical connection; it can be a direct connection or an indirect connection through an intermediate medium, it can be the internal connection of two elements or the interaction relationship between two elements, unless otherwise clearly defined. For those skilled in the art, the specific meanings of the above terms in the present disclosure can be understood according to the specific circumstances.

In the present disclosure, when an element is referred to as being “fixed to” or “disposed on” another element, it may be directly on the other element or there may be an intermediate element. When an element is considered to be “connected to” another element, it may be directly connected to the other element or there may be an intermediate element at the same time. If present, the terms “vertical”, “horizontal”, “upper”, “lower”, “left”, “right” and similar expressions are for illustrative purposes only and are not intended to be the only embodiment.

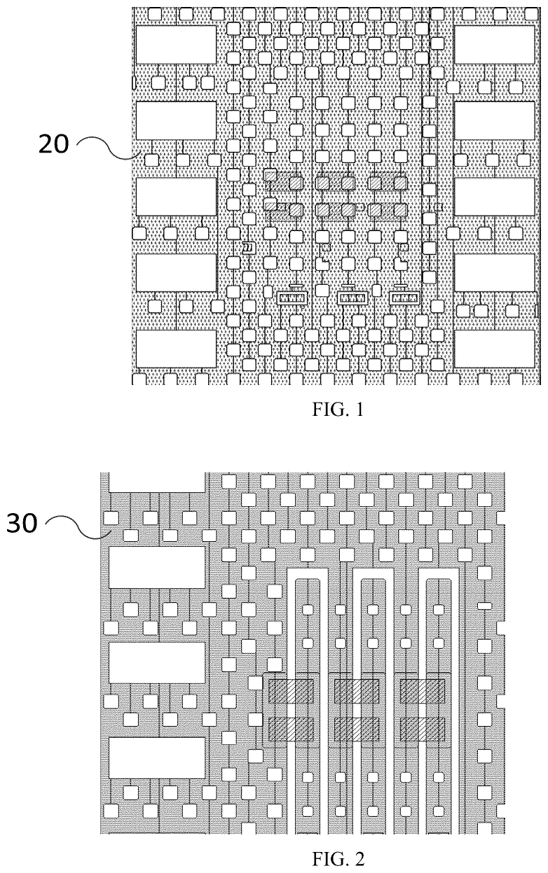

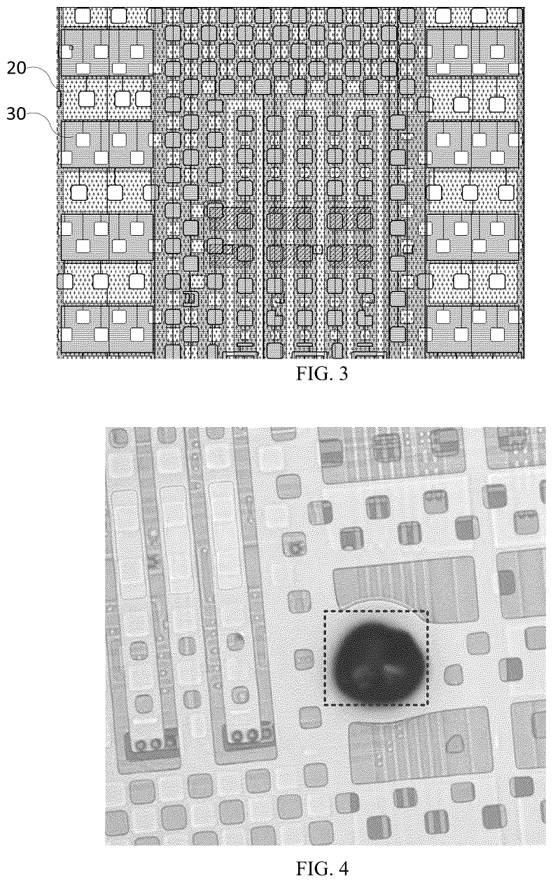

FIG. 1 illustrates a local top view of a first power line layer consistent with various disclosed embodiments in the present disclosure. FIG. 2 illustrates a local top view of a second power line layer consistent with various disclosed embodiments in the present disclosure. FIG. 3 illustrates a local top view of a first power line layer and a second power line layer after being stacked. As shown in FIG. 1 to FIG. 3, the first power line layer 20 and the second power line layer 30 are disposed on the entire surface, and the first power line layer 20 and the second power line layer 30 have a large overlapping area. During the preparation, transportation, and other processes, an insulating film layer between the first power line layer 20 and the second power line layer 30 is easily broken by the influence of foreign objects and external forces, causing the first power line layer 20 and the second power line layer 30 to deform and become conductive, and thereby causing a short circuit problem. FIG. 4 is a schematic diagram of a short circuit caused by foreign objects, and the dotted box area in FIG. 4 is the short circuit position. Since the first power line layer 20 and the second power line layer 30 need to provide positive power signals and negative power signals for the pixel circuits of the display panel, when a short circuit occurs in a certain area, the signals provided by the entire first power line layer and the second power line layer will be abnormal, resulting in serious consequences such as the product not lighting up or burning.

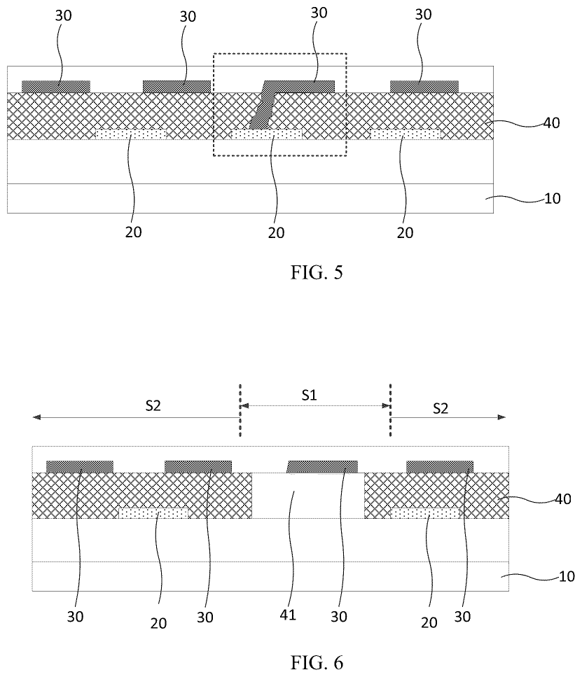

The present disclosure provides a display panel, to a least partially alleviate the above problems. FIG. 5 shows a cross-sectional view of a display panel provided by the embodiments of the present disclosure when a short circuit occurs between a first power line layer and a second power line layer. As shown in FIG. 5, in one embodiment, the display panel may include a substrate 10, and a first power line layer 20 and a second power line layer 30 located on the substrate 10.

The first power line layer 20 may be disposed between the second power line layer 30 and the substrate 10, and the first power line layer 20 and the second power line layer 30 may be insulated and overlap with each other. For example, an insulating layer 40 may be disposed between the first power line layer 20 and the second power line layer 30, to achieve electrical insulation between the first power line layer 20 and the second power line layer 30. It should be noted that the present disclosure does not limit the number of insulating layers between the first power line layer 20 and the second power line layer 30 and the type of insulating layers.

In some embodiments, there may also be other film layers between the substrate 10 and the first power line layer 20, such as a metal layer, an insulating layer, etc., which are simplified in FIG. 5, and it is not limited to having only one film layer between the substrate 10 and the first power line layer 20. In practical applications, the number and type of film layers between the substrate 10 and the first power line layer 20 may be set according to the needs of the display panel.

As shown in FIG. 5, because of the influence of foreign objects or external forces, the insulating film layer between the first power line layer 20 and the second power line layer 30 may be broken, such that the first power line layer 20 and the second power line layer 30 are deformed and conductive, and the first power line layer 20 and the second power line layer 30 may form a short circuit at the dotted box position in FIG. 5.

To avoid the problems of product failure, burning, etc. caused by abnormal signal provision because of the short circuit between the first power line layer and the second power line layer, in one embodiment of the present disclosure, a first isolation groove and/or a second isolation groove may be disposed in the short circuit failure area. By setting the first isolation groove and/or the second isolation groove in the short circuit failure area, the first isolation groove may insulate a portion of the first power line layer in the short circuit failure area and another portion of the first power line layer in the non-short circuit failure area; and, the second isolation groove may insulate a portion of the second power line layer in the short circuit failure area and another portion of the second power line layer in the non-short circuit failure area.

It should be noted that the first isolation groove insulates the portion of the first power line layer in the short circuit failure area and the other portion of the first power line layer in the non-short circuit failure area, including: the first isolation groove removes a part of the first power line layer at the short circuit position between the first power line layer and the second power line layer in the short circuit failure area; or, surrounding the short circuit position of the first power line layer and the second power line layer, the portion of the first power line layer in the short circuit failure area and the other portion of the first power line layer in the non-short circuit failure area are disconnected. The second isolation groove may insulate the portion of the second power line layer in the short-circuit failure area and the other portion of the second power line layer in the non-short-circuit failure area, including: the second isolation groove removes a part of the second power line layer at the short-circuit position between the first power line layer and the second power line layer in the short-circuit failure area; or, surrounding the short-circuit position of the first power line layer and the second power line layer, the portion of the second power line layer in the short-circuit failure area and the other portion of the second power line layer in the non-short-circuit failure area area are disconnected.

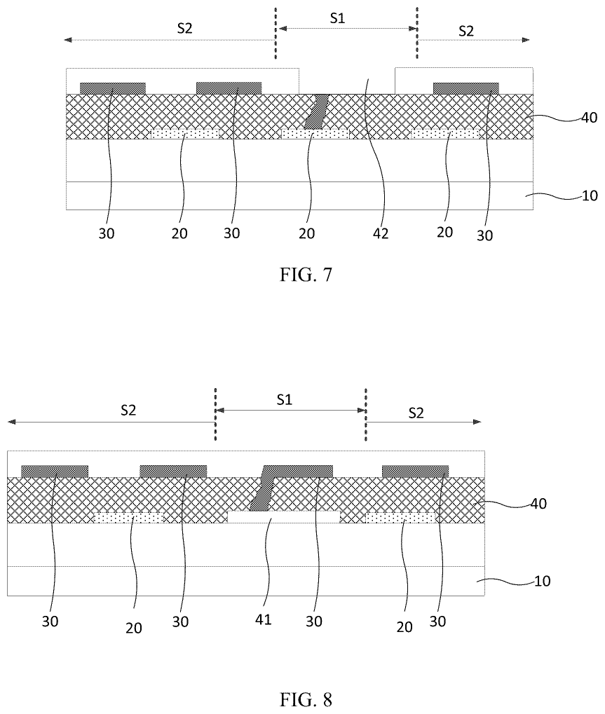

FIG. 6 illustrates a cross-sectional view of a repaired display panel provided in an embodiment of the present disclosure. FIG. 7 is another cross-sectional view of a repaired display panel provided in another embodiment of the present disclosure. As shown in FIG. 6, in one embodiment, the display panel may have a short-circuit failure area S1 and a non-short-circuit failure area S2. The display panel exemplarily shown in FIG. 6 may be provided with a first isolation groove 41 in the short-circuit failure area S1. The first isolation groove 41 may insulate a portion of the first power line layer 20 in the short-circuit failure area S1 and another portion of the first power line layer 20 in the non-short-circuit failure area S2. Since the first power line layer 20 may be arranged on the entire surface, when the first power line layer 20 and the second power line layer 30 are short-circuited, the signals on the first power line layer 20 and the second power line layer 30 may be abnormal. In the present embodiment, the first isolation groove 41 may be set to insulate the portion of the first power line layer 20 of the short-circuit failure area S1 and the other portion of the first power line layer 20 in the non-short-circuit failure area S2. After the first isolation groove 41 is set, since the other portion of the first power line layer 20 in the non-short-circuit failure area S2 may be no longer connected to the portion of the first power line layer 20 in the short-circuit failure area S1, the abnormal signal received by the portion of the first power line layer 20 in the short-circuit failure area S1 because of the short circuit may be no longer transmitted to the other portion of the first power line layer 20 in the non-short-circuit failure area S2. Therefore, the other portion of the first power line layer 20 in the non-short-circuit failure area S2 may also guarantee a normal power signal. As shown in FIG. 6, exemplarily, a part of the first power line layer at the short-circuit position of the first power line layer 20 and the second power line layer 30 may be removed through the first isolation groove 41, such that the other portion of the first power line layer 20 in the non-short-circuit failure area S2 may provide a normal signal.

In another embodiment, as shown in FIG. 7, the display panel may have a short circuit failure area S1 and a non-short circuit failure area S2. As shown in FIG. 7, a second isolation groove 42 may be disposed in the short circuit failure area S1. The second isolation groove 42 may insulate a portion of the second power line layer 30 in the short circuit failure area S1 and another portion of the second power line layer 30 in the non-short circuit failure area S2. Since the second power line layer 30 is disposed on the entire surface, when the first power line layer 20 and the second power line layer 30 are short-circuited, the signals on the first power line layer 20 and the second power line layer 30 may be abnormal. In the present embodiment, the second isolation groove 42 may be set to insulate the portion of the second power line layer 30 in the short circuit failure area S1 and the other portion of the second power line layer 30 in the non-short circuit failure area S2. After the second isolation groove 42 is set, since the other portion of the second power line layer 30 in the non-short circuit failure area S2 is no longer connected to the portion of the second power line layer 30 in the short circuit failure area S1 (for example, a part of the second power line layer at the short circuit position of the first power line layer 20 and the second power line layer 30 is removed by the second isolation groove 42, as shown in FIG. 7), the abnormal signal received by the portion of the second power line layer 30 in the short circuit failure area S1, because of the short circuit, may no longer be transmitted to the other portion of the second power line layer 30 in the non-short circuit failure area S2. Therefore, the other portion of the second power line layer 30 in the non-short circuit failure area S2 may still ensure a normal power signal.

It should be noted that the short circuit failure area refers to an area where the normal power signal cannot be provided to the display panel because of the short circuit between the first power line layer and the second power line layer, and the non-short circuit failure area refers to an area that is able to provide a normal power signal to the display panel.

In some embodiments, in a direction perpendicular to a plane where the display panel is located, the first isolation groove may at least penetrate the first power line layer; or, in the direction perpendicular to the plane where the display panel is located, the second isolation groove may at least penetrate the second power line layer.

In the present disclosure, to ensure that the portion of the first power line layer in the short-circuit failure area and the other portion of the first power line layer in the non-short-circuit failure area are able to be electrically disconnected, the first isolation groove may be set to at least penetrate the first power line layer in the direction perpendicular to the plane where the display panel is located, and a part of the first power line layer in a part of the short-circuit failure area may be removed by the first isolation groove, such that the portion of the first power line layer in the short-circuit failure area and the other portion of the first power line layer in the non-short-circuit failure area may be electrically disconnected, as shown in FIG. 8. For example. to ensure that the portion of the second power line layer in the short-circuit failure area and the other portion of the second power line layer in the non-short-circuit failure area are able to be electrically disconnected, the second isolation groove may be set to at least penetrate the second power line layer in the direction perpendicular to the plane where the display panel is located, and a part of the second power line layer in a part of the short-circuit failure area may be removed through the second isolation groove, so that the portion of the second power line layer in the short-circuit failure area and the other portion of the second power line layer in the non-short-circuit failure area may be electrically disconnected, as shown in FIG. 7.

In some embodiments, in the direction perpendicular to the substrate, the first isolation groove may extend to at least a portion of the insulating layer between the first power line layer and the second power line layer. And/or, in the direction perpendicular to the substrate, the second isolation groove may extend to at least a portion of the insulating layer between the first power line layer and the second power line layer.

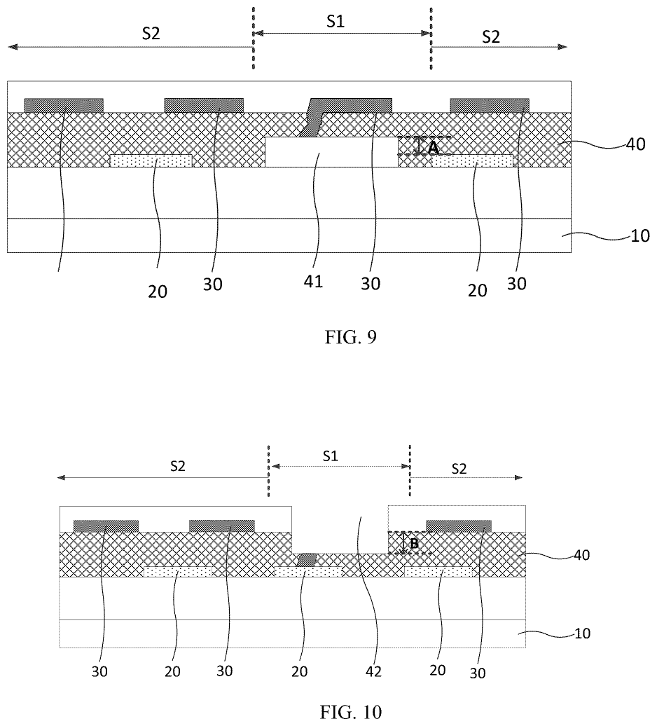

As shown in FIG. 9, in one embodiment, the insulating layer 40 may be disposed between the first power line layer and the second power line layer, to realize electrical insulation between the first power line layer 20 and the second power line layer 30. In the process of forming the first isolation groove 41, to avoid the failure to remove the thickness of the first power line layer 20 to be etched because of process errors or other reasons, a certain degree of over-etching may be performed when removing the first power line layer 20. That is, in the direction perpendicular to the substrate 10, the first isolation groove 41 may extend to at least a portion of the insulating layer 40 between the first power line layer 20 and the second power line layer 30, such that the first power line layer 20 to be etched in the short-circuit failure area S1 in the direction perpendicular to the substrate 10 may be completely removed, thereby realizing that the portion of the first power line layer 20 in the short-circuit failure area S1 and the other portion of the first power line layer 20 in the non-short-circuit failure area S2 may be electrically disconnected. As shown in FIG. 9, exemplarily, after etching the first power line layer 20, the insulating layer 40 with a thickness of A may be further etched.

Also, when forming the first isolation groove 41 in the short circuit failure area, to avoid the failure to remove the thickness of the second power line layer 30 to be etched because of process errors or other reasons, a certain degree of over-etching may be performed when removing the second power line layer 30. That is, in the direction perpendicular to the substrate 10, the second isolation groove 42 may extend to at least a portion of the insulating layer 40 between the first power line layer 20 and the second power line layer 30, such that the second power line layer 30 to be etched in the short-circuit failure area S1 in the direction perpendicular to the substrate 10 may be completely removed, thereby realizing that the portion of the second power line layer 30 in the short-circuit failure area S1 and the other portion of the second power line layer 30 in the non-short-circuit failure area S2 may be electrically disconnected. As shown in FIG. 9, exemplarily, after etching the second power line layer 30, the insulating layer 40 with a thickness of B may be further etched.

In some other embodiments, the short-circuit failure area may be provided with a first isolation groove, and an insulating layer may be provided between the first isolation groove and the second power line layer; or, the short-circuit failure area may be provided with a second isolation groove, and an insulating layer may be provided between the first isolation groove and the first power line layer.

As shown in FIG. 9, in one embodiment, when the first isolation groove 41 is provided in the short-circuit failure area S1, the insulating layer 40 below the second power line layer 30 may not be completely removed, that is, a partial thickness of the insulating layer 40 may be retained between the first isolation groove 41 and the second power line layer 30. While achieving the insulation of the portion of the first power line layer 20 in the short-circuit failure area S1 and the other portion of the first power line layer 20 in the non-short-circuit failure area S2 through the first isolation groove 41, the second power line layer 30 may also be protected by a partial thickness of the insulating layer 40.

As shown in FIG. 10, in another embodiment, when the second isolation groove 42 is set in the short-circuit failure area S1, the insulating layer 40 above the first power line layer 20 may not be completely removed, that is, a partial thickness of the insulating layer 40 may be retained between the second isolation groove 42 and the first power line layer 20. While isolating the portion of the second power line layer 30 in the short-circuit failure area S1 and the other portion of the second power line layer 30 in the non-short-circuit failure area S2 through the second isolation groove 42, the first power line layer 20 may also be protected by a partial thickness of the insulating layer 40.

In some embodiments, in the direction perpendicular to the substrate, metal layers between the first power line layer and the substrate may not overlap with the first isolation groove and/or the second isolation groove.

In the direction perpendicular to the substrate, multiple film layers, including, for example, various metal layers of transistors, a capacitor metal layer, or insulating layers between various metal layers, may be set between the first power line layer and the substrate.

When preparing and forming the first isolation groove and/or the second isolation groove, when the metal layers between the first power line layer and the substrate overlap with isolation grooves (including the first isolation groove and/or the second isolation groove), the metal layers between the first power line layer and the substrate may be damaged during the preparation process. Therefore, in the embodiment of the present disclosure, it may be set that the metal layers between the first power line layer and the substrate do not overlap with the first isolation groove and/or the second isolation groove.

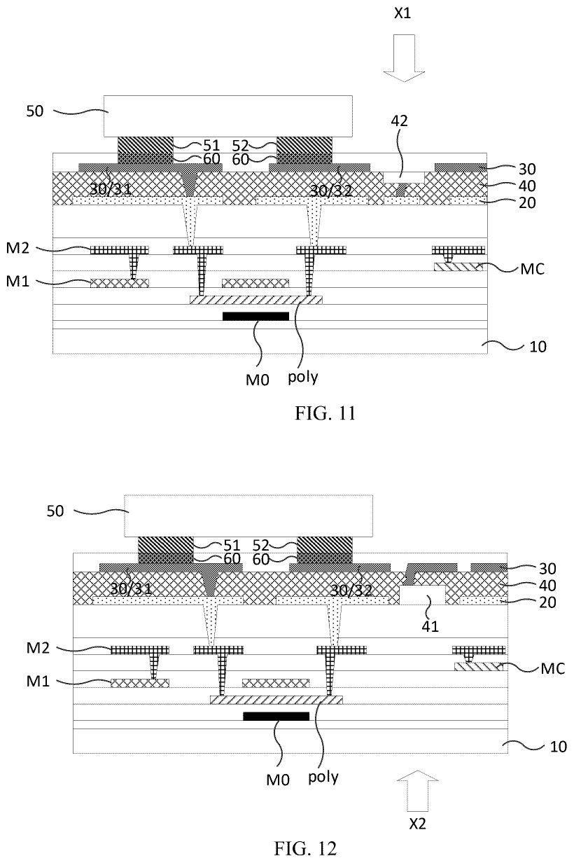

FIG. 11 is a cross-sectional view of another display panel provided by an embodiment of the present disclosure. As shown in FIG. 11, the metal layers between the first power line layer 20 and the substrate 10 may include, for example, a metal layer M0, a metal layer M1, a metal layer M2, and a metal layer MC. The metal layer M0 may include, for example, a light shielding layer to prevent light from causing photo-induced degradation effects on an active layer poly of a transistor. The metal layer M1 may include, for example, a gate of a transistor, the metal layer MC may include, for example, a plate layer of a capacitor, and the metal layer M2 may include, for example, a source and drain of a transistor.

The process method for forming the first isolation groove and the second isolation groove is not limited in the present disclosure. Taking laser etching as an example, when the second power line layer is irradiated on a side away from the substrate (for the sake of simplicity of description, the embodiment with irradiation from the front of the display panel, i.e., the direction of the arrow X1 in the figure), when the metal layers between the first power line layer 20 and the substrate 10 overlap with the second isolation groove 42, the heat in the laser etching when preparing and forming the second isolation groove 42 may damage metal (the metal layers between the first power line layer 20 and the substrate 10) overlapping with the second isolation groove 42. Therefore, in the embodiment of the present disclosure, the metal layers between the first power line layer and the substrate may be set to not overlap with the second isolation groove 42.

FIG. 12 is a cross-sectional view of another display panel provided by an embodiment of the present disclosure. As shown in FIG. 12, the metal layers between the first power line layer 20 and the substrate 10 may include, for example, a metal layer M0, a metal layer M1, a metal layer M2, and a metal layer MC. The metal layer M0 may include, for example, a light shielding layer to prevent light from causing photo-induced degradation effects on the active layer poly of the transistor. The metal layer M1 may include, for example, the gate of the transistor, the metal layer MC may include, for example, the plate layer of the capacitor, and the metal layer M2 may include, for example, the source and drain of the transistor.

When the substrate is irradiated from a side away from the first power line layer (for the sake of simplicity, the embodiment with irradiation from the back of the display panel, i.e., the direction of arrow X2 in the figure, is used as an example), when the metal layers between the first power line layer 20 and the substrate 10 overlap with the first isolation groove 41, the laser when preparing and forming the first isolation groove 41 may penetrate metal of the stacked layers and then etch the first power line layer 20 and the second power line layer 30, which is more likely to cause damage to the metal layers between the first power line layer 20 and the substrate 10. Therefore, in the embodiment of the present disclosure, the metal layers between the first power line layer and the substrate may be set to not overlap with the first isolation groove 41.

In some embodiments, the second power line layer may be bonded to light emitting elements through a bonding layer.

For example, as shown in FIG. 11 and FIG. 12, the display panel may further include light emitting elements 50, and each light emitting element 50 may include an anode 51 and a cathode 52. The second power line layer may be connected to the light emitting elements 50 as a connection structure in the display panel. The second power line layer 30 may be bonded to the anode 51 and the cathode 52 of the light emitting element 50 through a bonding layer 60. The second power line layer 30 may be a metal layer of the display panel that is closest to the light emitting element except the bonding layer. Therefore, when the first isolation groove 41 and/or the second isolation groove 42 are prepared by laser etching, it may be more convenient to irradiate the front of the display panel to avoid penetrating other metal film layers during laser irradiation. As shown in FIG. 11 and FIG. 12, a part of the second power line layer 30 bonded to the anode 51 of the light emitting element 50 is marked as 31, and another part of the second power line layer 30 bonded to the cathode 52 of the light emitting element 50 is marked as 32.

In some embodiments, the first isolation groove and the second isolation groove may be connected in the direction perpendicular to the plane where the display panel is located.

The first isolation groove and the second isolation groove may be set to be connected, that is, the first isolation groove and the second isolation groove may be set at the same time and may at least partially overlap in the direction perpendicular to the plane where the display panel is located. To further ensure that the problem of abnormal power signal caused by the short circuit of the first power line layer and the second power line layer is avoided, in one embodiment, the first isolation groove and the second isolation groove may be set at the same time, and the first isolation groove and the second isolation groove may be connected to achieve the insulation of the first power line layer of the short-circuit failure area and the non-short-circuit failure area at the same position, and the insulation of the second power line layer, at the same position.

It should be noted that the embodiments of the present disclosure do not limit the morphology, width, overlapping position, etc. of the first isolation groove and the second isolation groove.

In some embodiments, the first isolation groove and/or the second isolation groove may be located at the short-circuit point in the short-circuit failure area.

In one embodiment of the present disclosure, the display panel may be repaired at the short-circuit point of the short-circuit failure area. The short-circuit point of the short-circuit failure area may refer to the position where the first power line layer and the second power line layer are short-circuited. The short-circuit point may be, for example, the position shown in the dotted box of FIG. 5. FIG. 6 to FIG. 10 all show the display panel repaired at the short-circuit point of the short-circuit failure area. For example, in FIG. 6, the first isolation groove 41 is located at the short-circuit point of the short-circuit failure area S1. For another example, as shown in FIG. 7, the second isolation groove 42 is located at the short-circuit point of the short-circuit failure area S1. By repairing directly at the short-circuit point, the short-circuit failure area formed may be small, which may reduce the area of bad pixels in the display panel.

In some embodiments, a vertical projection of the short-circuit point on the substrate may be located within a vertical projection of the first isolation groove on the substrate; and/or, a vertical projection of the short-circuit point on the substrate may be located within a vertical projection of the second isolation groove on the substrate.

When the display panel is repaired at the short-circuit point through the first isolation groove, in one embodiment, it may be set that the vertical projection of the short-circuit point on the substrate is located within the vertical projection of the first isolation groove on the substrate, such that the first isolation groove may at least cover the short-circuit point, thereby completely insulating the first power line layer of the short-circuit failure area and the non-short-circuit failure area.

When the display panel is repaired at the short-circuit point through the second isolation groove, in one embodiment, it may be set that the vertical projection of the short-circuit point on the substrate is located within the vertical projection of the second isolation groove on the substrate, such that the second isolation groove may at least cover the short-circuit point, thereby completely insulating the second power line layer of the short-circuit failure area and the non-short-circuit failure area.

In some embodiments, the area of the short-circuit point may be less than or equal to the laser etching spot area of the first isolation groove and the second isolation groove.

When the first isolation groove and/or the second isolation groove are formed by laser etching, when the area of the short-circuit point is less than the laser etching spot area, the first isolation groove and/or the second isolation groove may be set at the short-circuit point by laser etching. Since the area of the short-circuit point is smaller than the area of the laser etching spot, when laser etching is used, the first isolation groove and/or the second isolation groove may be conveniently formed directly at the short-circuit point.

In some embodiments, the first isolation groove and/or the second isolation groove may be arranged in a ring shape in the short circuit failure area.

In one embodiment of the present disclosure, the first isolation groove and/or the second isolation groove may be arranged in a ring shape in the short circuit failure area. For example, the damage at the short circuit position of the first power line layer and the second power line layer may be relatively deep, or the area of the short circuit may be relatively large. When laser etching is performed directly at the short circuit position, because of the uneven thickness and blurred boundary of the short-circuited metal film layer at the short circuit position, continuous irradiation of the laser spot at the short circuit position may cause the metal at the position to be melted together, and the problem that the short circuit metal at different positions may not be completely etched because of the different thickness of the short circuit metal. Therefore, to avoid the above problems caused by repair operations such as laser irradiation at the short circuit position, in the embodiment of the present disclosure, the first isolation groove and/or the second isolation groove may be arranged in a ring shape in the short circuit failure area, and the portion of the first power line layer at the short circuit failure area and the other portion of the first power line layer at the non-short circuit failure area may be insulated by the structure of the first isolation groove in a ring shape, and the portion of the second power line layer at the short circuit failure area and the other portion of the second power line layer at the non-short circuit failure area may be insulated by the structure of the second isolation groove in a ring shape.

In some embodiments, the short-circuit failure area may include a short-circuit point, and the first isolation groove and/or the second isolation groove may be arranged around the short-circuit point.

In one embodiment of the present disclosure, the isolation repair may be performed around the short-circuit point. The short-circuit point may be a position where the first power line layer and the second power line layer are short-circuited. In the embodiment of the present disclosure, the first isolation groove and/or the second isolation groove may be arranged around the short-circuit point to form a short-circuit failure area.

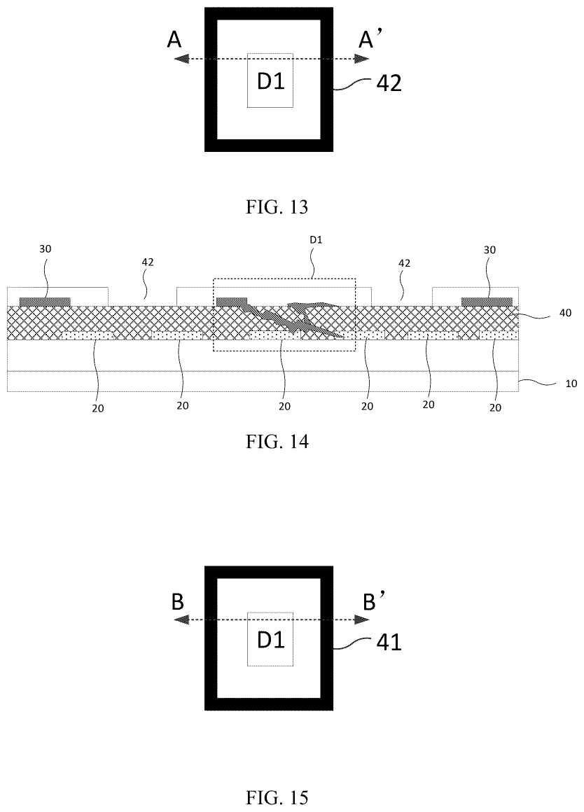

FIG. 13 is a partial top view of a display panel provided by one embodiment of the present disclosure, and FIG. 14 is a cross-sectional view along the AA′ direction in FIG. 13. In the embodiment shown in FIG. 13 and FIG. 14, D1 is a short-circuit point, and the ring-shaped second isolation groove 42 may be arranged around the short-circuit point D1. When the short-circuit point is large and deep, the first power line layer, the second power line layer and other metal layers of the display panel may be connected at the short-circuit point. When the short-circuit point is repaired, for example, by laser etching, the transmission of laser energy in the metal layers may cause the metal layers at the short-circuit point to melt together, causing further damage to the display panel. Therefore, in the embodiment of the present disclosure, the second isolation groove may be arranged around the short-circuit point to disconnect the portion of the second power line layer in the short-circuit failure area and the other portion of the second power line layer in the non-short-circuit failure area, instead of directly repairing the short-circuit point. The second power line layer around the short-circuit point may be a metal layer of normal thickness. Therefore, when laser etching is used, it may be easier to control the laser etching process and form the second isolation groove according to the set etching depth. It should be noted that the second isolation groove may form a closed-loop structure without limiting the shape.

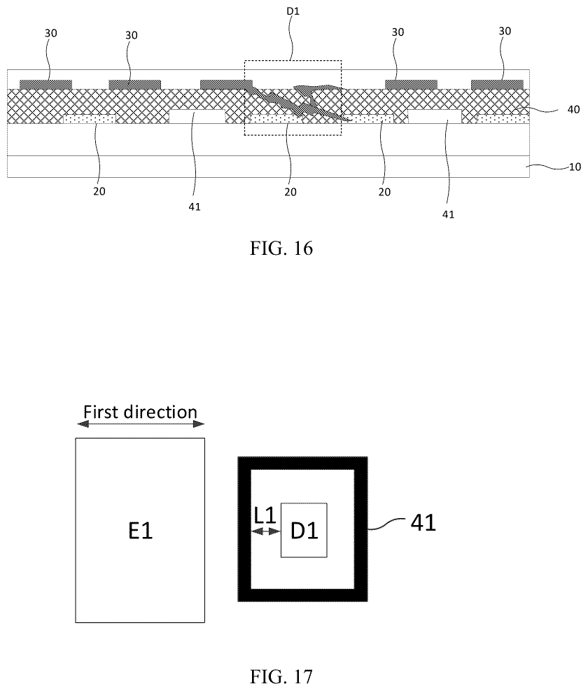

FIG. 15 is a partial top view of another display panel provided by one embodiment of the present disclosure, and FIG. 16 is a cross-sectional view along the BB′ direction in FIG. 15. In the embodiment shown in FIG. 15 and FIG. 16, D1 is a short-circuit point, and an annular first isolation groove 41 is arranged around the short-circuit point D1. The first isolation groove 41 may surround the short-circuit position of the first power line layer and the second power line layer to disconnect the portion of the first power line layer in the short-circuit failure area and the other portion of the first power line layer in the non-short-circuit failure area. For example, when the short-circuit point is repaired, when laser etching is used, the transmission of laser energy in the metal layers may cause the metal layers at the short-circuit point to melt together, causing further damage to the display panel. Therefore, in the embodiment of the present disclosure, the short-circuit point around the first isolation groove 41 may be isolated, to disconnect the portion of the first power line layer in the short-circuit failure area and the other portion of the first power line layer in the non-short-circuit failure area, instead of directly repairing the short-circuit point. The first power line layer around the short-circuit point may be a metal layer of normal thickness. Therefore, when laser etching is used, it may be easier to control the laser etching process and form the first isolation groove according to the set etching depth. It should be noted that the first isolation groove may form a closed-loop structure as an example, without limiting the shape.

In some embodiments, the maximum width of the short-circuit point may be larger than the width of the first isolation groove and/or the second isolation groove.

When laser etching is used to form the first isolation groove and/or the second isolation groove, when the maximum width of the short-circuit point is greater than the width of the first isolation groove and/or the second isolation groove, that is, when the area of the short-circuit point in the display panel is larger than the area of the laser etching spot, it may mean that the area of the short-circuit point is large, and a single laser spot irradiation is not able to repair the whole short-circuit point position. Using a laser spot to irradiate the short-circuit position multiple times may cause the metal layers at the short-circuit position to fuse together, causing damage to the display panel. Further, when laser etching is performed at the short-circuit point, the thickness of the metal of the short circuit at different positions in the short-circuit area of a larger area may be different, and it may be difficult to control the process parameters of laser etching. The edge of the short-circuit point may be irregular, and it may not be easy to control the complete etching of the edge position by in-situ etching at the short-circuit point. In view of the above situation, a first annular isolation groove may be set around the short-circuit point to insulate the portion of the first power line layer in the short-circuit failure area and the other portion of the first power line layer in the non-short-circuit failure area; and/or a second annular isolation groove may be set around the short-circuit point to insulate the portion of the second power line layer in the short-circuit failure area and the other portion of the second power line layer in the non-short-circuit failure area.

In some embodiments, in the plane direction parallel to the substrate, the distance between the first isolation groove and the short-circuit point may be larger than 30 μm; and/or, the distance between the second isolation groove and the short-circuit point may be larger than 30 μm.

Since the edge contour of the short-circuit point is not neat, to avoid etching the edge position of the short-circuit point when setting the first isolation groove and/or the second isolation groove around the short-circuit point, in one embodiment of the present disclosure, the first isolation groove and/or the second isolation groove may be disposed in an area within a certain distance range from the short-circuit point. In the embodiment of the present disclosure, in the plane direction parallel to the substrate, the distance between the first isolation groove and the short-circuit point may be larger than 30 μm; and/or, the distance between the second isolation groove and the short-circuit point may be larger than 30 μm, to avoid etching the edge position of the short-circuit point because of the repair position and the short-circuit point being too close, resulting in the first power line layer or the second power line layer in the short-circuit failure area and the non-short-circuit failure area not being completely disconnected.

In some embodiments, in the plane direction parallel to the substrate, the ratio of the distance between the first isolation groove and/or the second isolation groove and the short-circuit point to the size of the light-emitting element arrangement area in the first direction may be less than 1.

The distance between the first isolation groove and/or the second isolation groove and the short-circuit point may be parallel to the first direction.

The embodiment of the present disclosure may be applied to a Micro LED display panel, etc. FIG. 17 is a schematic diagram of the positional relationship between the isolation groove and the light-emitting element arrangement area provided by one embodiment of the present disclosure. In the embodiment shown in FIG. 17, E1 is the light-emitting element arrangement area, and the light-emitting element arrangement area E1 is the area where the light-emitting element is bonded and set when the light-emitting element is transferred in an array. FIG. 17 exemplarily sets the first isolation groove 41, and the distance between the first isolation groove 41 and the short-circuit point D1 in the first direction is L1. The first direction in FIG. 17 is the direction of the double arrow, and the ratio of the distance L1 between the first isolation groove 41 and the short-circuit point D1 to the size of the light-emitting element arrangement area E1 in the first direction may be less than 1, indicating that the distance L1 between the first isolation groove 41 and the short-circuit point D1 in the first direction is less than the size of the light-emitting element in the first direction. This setting may prevent the dark spot area from being too large caused by the distance L1 between the first isolation groove 41 and the short-circuit point D1 being too large.

FIG. 17 exemplarily describes the embodiment where the ratio of the distance between the first isolation groove and the short-circuit point to the size of the light-emitting element arrangement area in the first direction is less than 1. Another embodiment where the ratio of the distance between the second isolation groove and the short-circuit point to the size of the light-emitting element arrangement area in the first direction is less than 1 is similar to this embodiment, and will not be repeated here.

In some embodiments, the ratio of the area of the short-circuit failure area to the area of the light-emitting element arrangement area may be less than 3.

In the present embodiment, the first power line layer and the second power line layer may be short-circuited, and the short-circuit failure area may be generated by setting the first isolation groove and/or the second isolation groove. The short-circuit failure area is not able to provide a normal power signal to the display panel, and dark spots may be generated correspondingly. Based on this, in one embodiment, the ratio of the area of the short-circuit failure area to the area of the light-emitting element arrangement area may be set to be less than 3, that is, the area of the short-circuit failure zone may be less than the area of three light-emitting element arrangement areas, to prevent the large area of the short-circuit failure area from causing dark spots of a large area to affect the display effect of the display panel.

In some embodiments, the distance between the first isolation groove and/or the second isolation groove and a nearest neighboring light-emitting element arrangement area may be larger than 20 μm.

In one embodiment of the present disclosure, when the first isolation groove and/or the second isolation groove are set, the distance between the first isolation groove and/or the second isolation groove and the nearest light-emitting element arrangement area may be larger than 20 μm.

When the display panel is repaired before the array transfers light-emitting elements, in the embodiment of the present disclosure, the first isolation groove and/or the second isolation groove may be set to be more than 20 μm away from the nearest light-emitting element arrangement area, to avoid damage to the circuit layer of the light-emitting element arrangement area because of the first isolation groove and/or the second isolation groove being too close to the light-emitting element arrangement area.

When the display panel is repaired after the array transfer of the light-emitting elements, in the embodiment of the present disclosure, the first isolation groove and/or the second isolation groove may be set to be more than 20 μm away from the nearest light-emitting element arrangement area, which may also avoid the damage of the bonded light-emitting elements because of the first isolation groove and/or the second isolation groove being too close to the light-emitting element arrangement area.

In some embodiments, the second power line layer may include a first electrode portion and a second electrode portion electrically insulated. In the light-emitting element arrangement area, the first electrode portion may be used to electrically connect to the anode of the light-emitting element, and the second electrode portion may be used to electrically connect to the cathode of the light-emitting element;

In the direction perpendicular to the substrate, the second isolation groove may not overlap with the first electrode portion and/or the second electrode portion in the light-emitting element arrangement area.

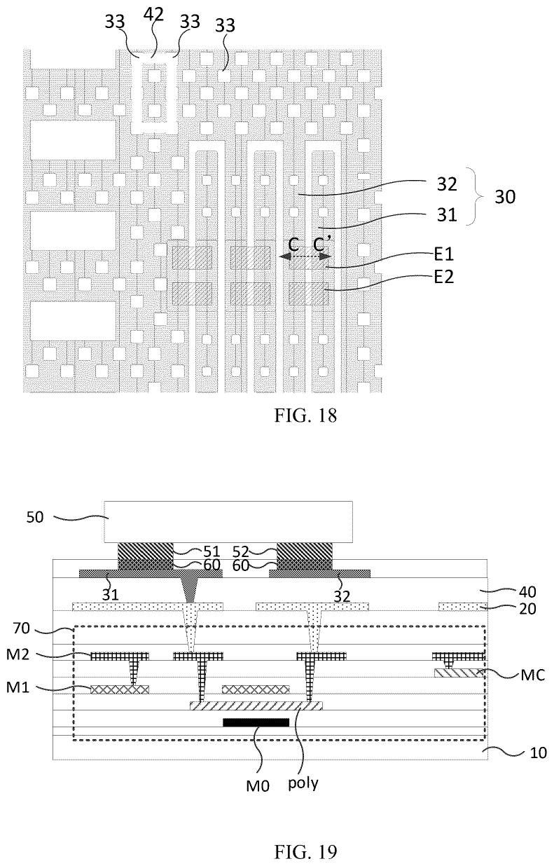

FIG. 18 is a partial top view of another second power line layer provided by one embodiment of the present disclosure, and FIG. 19 is a cross-sectional view along the CC′ direction in FIG. 18. As shown in FIG. 18 and FIG. 19, the second power line layer 30 may include a first electrode portion 31 and a second electrode portion 32 electrically insulated. In the light-emitting element arrangement area E1, the first electrode portion 31 may be used to electrically connect to the anode 51 of the light-emitting element 50, and the second electrode portion 32 may be used to electrically connect to the cathode 52 of the light-emitting element 50. The first electrode portion 31 and the second electrode portion 32 may be insulated from each other in the second power line layer 30.

As shown in FIG. 19, the second power line layer 30 may be located on a side of the pixel circuit 70 away from the substrate 10, and the second power line layer 30 may include a first electrode portion 31 and a second electrode portion 32. The first electrode portion 31 and the second electrode portion 32 may be electrically insulated. Although the light-emitting element 50 is electrically connected to both the first electrode portion 31 and the second electrode portion 32, the first electrode portion 31 and the second electrode portion 32 may provide different electrical signals for the light-emitting element 50. The light-emitting element 50 may be electrically connected to the pixel circuit 70 through the first electrode portion 31. The light-emitting element 50 may include an anode 51 and a cathode 52. The anode 51 may be bonded to the bonding layer 60 on the first electrode portion 31, and the cathode 52 may be bonded to the bonding layer 60 on the second electrode portion 32, by laser irradiation or the like, to ensure the driving of the light-emitting element 50, thereby realizing the display luminescence of the display panel.

As shown in FIG. 18, the first electrode portion 31 and the second electrode portion 32 of the second power line layer 30 may need to receive corresponding electrical signals, and therefore cannot be disconnected by the isolation groove (including the first isolation groove and/or the second isolation groove). Therefore, to ensure that the light-emitting element is able to obtain the corresponding electrical signals through the first electrode portion 31 and the second electrode portion 32, the second isolation groove 42 may be set perpendicular to the substrate 10 so as not to overlap with the first electrode portion 31 and/or the second electrode portion 32 in the light-emitting element arrangement area E1.

In one embodiment shown in FIG. 18, a redundant repair area E2 may be also provided. When the light-emitting element in the light-emitting element arrangement area E1 fails, the light-emitting element in the light-emitting element arrangement area E1 may be removed by laser, and the light-emitting element may be reset in the redundant repair area E2. It should be noted that in other embodiments, the redundant repair area E2 may not be required, and the embodiment of the present disclosure does not limit this.

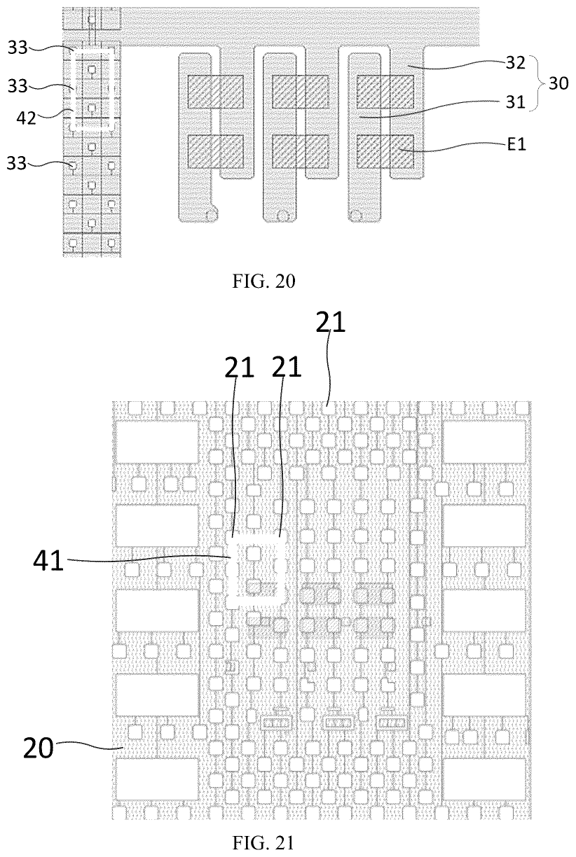

FIG. 18 is a partial structure of the second power line layer provided by one embodiment of the present disclosure. In some other embodiments, the second power line layer may also be arranged in other forms, such as shown in FIG. 20. In the embodiment shown in FIG. 20, the second power line layer 30 may be located on the side of the pixel circuit 70 away from the substrate 10, and the second power line layer 30 may include a first electrode portion 31 and a second electrode portion 32. The second isolation groove 42 may not overlap with the first electrode portion 31 and/or the second electrode portion 32 in the light-emitting element arrangement area E1 in the direction perpendicular to the substrate 10. The present disclosure does not limit the specific structural arrangement of the second power line layer. FIG. 18 and FIG. 20 are only two specific examples to illustrate the present disclosure.

In some embodiments, the second power line layer may include a first electrode portion and a second electrode portion electrically insulated. In the light-emitting element arrangement area, the first electrode portion may be used to electrically connect to the anode of the light-emitting element, and the second electrode portion may be used to electrically connect to the cathode of the light-emitting element. In the direction perpendicular to the substrate, the first isolation groove may overlap with the first electrode portion and/or the second electrode portion in the light-emitting element arrangement area.

The arrangement of the second power line layer in the present embodiment may refer to the structure shown in FIG. 18, for example. To avoid the first isolation groove being set on the second power line layer and overlapping with the first electrode portion and/or the second electrode portion of the light-emitting element arrangement area resulting in the light-emitting element being unable to obtain the corresponding electrical signals through the first electrode portion and the second electrode portion, in one embodiment of the present disclosure, the first isolation groove may be arranged to overlap with the first electrode portion and/or the second electrode portion in the light-emitting element arrangement area in the direction perpendicular to the substrate. For example, as shown in FIG. 21, in one embodiment, the first power line layer 20 may be provided with a first isolation groove 41, and the first isolation groove 41 may overlap with the first electrode portion 31 and/or the second electrode portion 32 of the second power line layer 30 in FIG. 18. Since the first power line layer is wirelessly prepared with the first electrode portion and/or the second electrode portion and an insulating layer is provided between the first power line layer and the second power line layer for insulation, when the first isolation groove is set in the first power line layer, its setting position may overlap with the first electrode portion and/or the second electrode portion of the second power line layer.

In some embodiments, the first power line layer may be provided with a plurality of first exhaust holes, and the first isolation groove may be connected to at least part of the plurality of first exhaust holes; and/or, the second power line layer may be provided with a plurality of second exhaust holes and the second isolation groove may be connected to at least part of the plurality of second exhaust holes.

In the process of forming the display panel, the display panel may need to undergo multiple film forming processes, and water vapor may be sealed in the process of preparing the organic layer. The first power line layer and the second power line layer may hinder the release of the gas, making the gas release more difficult, causing the display panel to easily bulge, and affecting the preparation yield and reliability of the display panel. Based on the above problems, in one embodiment of the present disclosure, a plurality of first exhaust holes may be disposed in the first power line layer, and/or a plurality of second exhaust holes may be disposed in the second power line layer. As shown in FIG. 21, the first power line layer 20 may include a plurality of first exhaust holes 21, and as shown in FIG. 18 and FIG. 20, the second power line layer 30 may include a plurality of second exhaust holes 33.

When the first isolation groove is set in the first power line layer 20, to save etching time, for example, as shown in FIG. 21, the first isolation groove 41 may be provided to be connected to at least part of the plurality of first exhaust holes 21. Therefore, only the first power line layer 20 between the part of the plurality of first exhaust holes 21 may be etched to form the first isolation groove 41. Similarly, when the second isolation groove 42 is set in the second power line layer 30, to save etching time, for example, as shown in FIG. 18 and FIG. 20, the second isolation groove 42 may be provided to be connected to at least part of the plurality of second exhaust holes 33. Therefore, only the second power line layer 30 between the part of the plurality of second exhaust holes 33 may be etched to form the second isolation groove 42.

In some embodiments, the display panel may further include a plurality of pixel circuits. One pixel circuit may include an amplitude modulation module and a pulse width modulation module. The first power line layer may include a first power line for providing a first power supply voltage to the amplitude modulation module.

To meet the requirements of high-resolution display panels, for example, a Micro LED display panel may use a pixel circuit combining pulse amplitude modulation (PAM) and pulse width modulation (PWM) to control the intensity of the driving current and the duration of the driving current to control the light-emitting state of the light-emitting element.

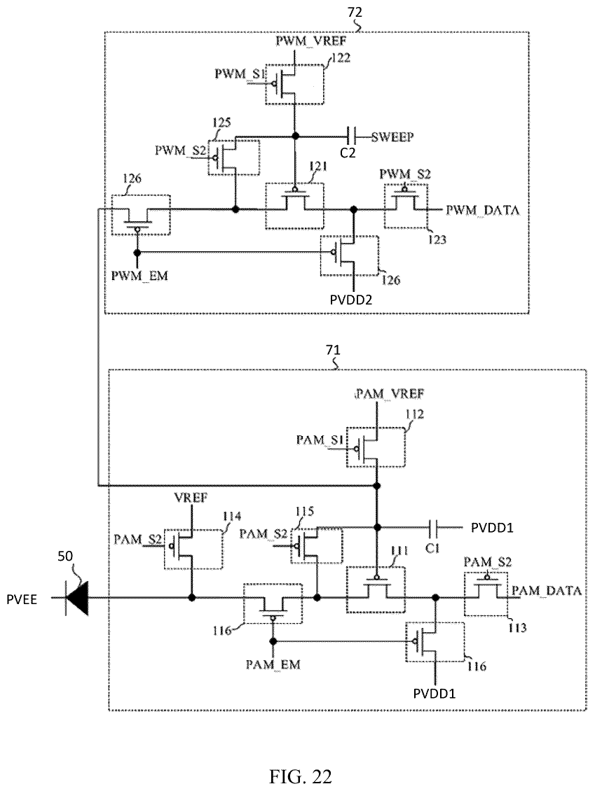

FIG. 22 is a structural schematic diagram of a pixel circuit provided by one embodiment of the present application. As shown in FIG. 22, in one embodiment, the pixel circuit 70 may include an amplitude modulation module 71 and a pulse width modulation module 72. The amplitude modulation module 71 may be connected to the pulse width modulation module 72, and the pixel circuit 70 may generate a driving current under the control of the amplitude modulation module 71 and the pulse width modulation module 72. The amplitude modulation module 71 may be used to control the amplitude of the driving current, and the pulse width modulation module 72 may be used to adjust the pulse width of the voltage applied to the anode of the light-emitting element 50. The amplitude modulation module 71 may include an amplitude driving submodule 111 and an amplitude resetting submodule 112. The amplitude resetting submodule 112 may be connected to the control terminal of the amplitude driving submodule 111. The amplitude resetting submodule 112 may be used to transmit a first reset signal PAM_REF to the control terminal of the amplitude driving submodule 111. The first reset signal PAM_REF may be used to reset the potential at the control terminal of the amplitude driving submodule 111. The amplitude modulation module 71 may include an amplitude data writing submodule 113. The amplitude data writing submodule 113 may be used to transmit a first data signal PAM_DATA to the amplitude driving submodule 111. Exemplarily, the amplitude data writing submodule 113 may be connected to the first terminal of the amplitude driving submodule 111. The first data signal PAM_DATA may be transmitted to the first terminal of the amplitude driving submodule 111 through the amplitude data writing submodule 113, and then transmitted to the control terminal of the amplitude driving submodule 111. The amplitude modulation module 71 may control the amplitude of the driving current based on the voltage value of the first data signal PAM_DATA, and the pulse width modulation module 72 may adjust the pulse width of the voltage applied to the anode of the light emitting element 50 based on the voltage value of the second data signal PWM_DATA. The amplitude modulation module 71 also may include an anode reset submodule 114, which may be connected to the anode of the light emitting element 50. The anode reset submodule 114 may be used to transmit a third reset signal VREF to the anode of the light emitting element 50.

The pulse width modulation module 72 may include a pulse width driving submodule 121 and a pulse width reset submodule 122. The pulse width reset submodule 122 may be connected to the control terminal of the pulse width driving submodule 121. The pulse width reset submodule 122 may be used to transmit a second reset signal PWM_REF to the control terminal of the pulse width driving submodule 121. The second reset signal PWM_REF may be used to reset the potential at the control terminal of the pulse width driving submodule 121. The pulse width modulation module 72 may include a pulse width data writing submodule 123. The pulse width data writing submodule 123 may be used to transmit a second data signal PWM_DATA to the pulse width driving submodule 121. Exemplarily, the pulse width data writing submodule 123 may be connected to the first terminal of the pulse width driving submodule 121. The second data signal PWM_DATA may be transmitted to the first terminal of the pulse width driving submodule 121 through the pulse width data writing submodule 123, and then transmitted to the control terminal of the pulse width driving submodule 121.

The control terminal of the amplitude reset submodule 112 may be connected to the scan line PAM_S1, the control terminal of the amplitude data writing submodule 113 may be connected to the scan line PAM_S2, the control terminal of the pulse width reset submodule 122 may be connected to the scan line PWM_S1, and the control terminal of the pulse width data writing submodule 123 may be connected to the scan line PWM_S2.

In one frame time, the scan line PAM_S1, the scan line PAM_S2, the scan line PWM_S1 and the scan line PWM_S2 may provide the conduction level in a certain order.

The amplitude modulation module 71 may also include a first compensation submodule 115, which may be connected between the control terminal and the second terminal of the amplitude driving submodule 111, and the first compensation submodule 115 may be used to compensate the threshold voltage of the amplitude driving submodule 111. The control terminal of the first compensation submodule 115 may be connected to the scan line PAM_S2.

The amplitude modulation module 71 may also include first light-emitting control modules 116. One first light-emitting control module 116 may be connected between the first power line PVDD1 and the first terminal of the amplitude driving submodule 111, and another first light-emitting control module 116 may be connected between the second terminal of the amplitude driving submodule 111 and the light-emitting element 50. The control terminal of the first light-emitting control module 116 may be connected to the first light-emitting control signal line PAM_EM.

The amplitude modulation module 71 may also include a first capacitor C1. The first terminal of the first capacitor C1 may be connected to the first power line PVDD1, and the second terminal of the first capacitor C1 may be connected to the control terminal of the amplitude driving submodule 111.

The pulse width modulation module 72 may also include a second compensation submodule 125. The second compensation submodule 125 may be connected between the control terminal and the second terminal of the pulse width driving submodule 121, and the second compensation submodule 125 may be used to compensate for the threshold voltage of the pulse width driving submodule 121. The control terminal of the second compensation submodule 125 may be connected to the scan line PWM_S2.

The pulse width modulation module 72 may also include second light-emitting control modules 126. One second light-emitting control module 126 may be connected between the second power line PVDD2 and the first terminal of the pulse width driving submodule 121, and the other second light-emitting control module 126 may be connected between the second terminal of the pulse width driving submodule 121 and the amplitude modulation module 71.

The pulse width modulation module 72 may also include a second capacitor C2. The first terminal of the second capacitor C2 may be connected to the sweep signal SWEEP, and the second terminal of the second capacitor C2 may be connected to the control terminal of the pulse width driving submodule 121. The sweep signal SWEEP may be a ramp signal in the shape of a triangular wave whose voltage value changes linearly with time. The pulse width modulation module 72 may control the duty cycle of the pixel circuit 70 to provide the light-emitting element with the driving current in the light-emitting stage according to the sweep signal SWEEP, thereby controlling the brightness of the light-emitting element. That is, the larger the duty cycle, the higher the brightness of the light-emitting element perceived by the human eye, and the smaller the duty cycle, the lower the brightness of the light-emitting element perceived by the human eye.

The first power line layer may include the above-mentioned first power line PVDD1, which is used to provide a first power supply voltage to the amplitude modulation module. PVEE in FIG. 22 is a third power line for providing a power signal to the cathode of the light-emitting element 50, and the third power line PVEE may be formed by the second power line layer.

In some embodiments, the power supply voltages of the first power line and the second power line may be set to be the same or different according to the pixel circuit setting requirements of the display panel. When the power supply voltages of the first power line and the second power line are the same, the first power line PVDD1 and the second power line PVDD2 may both be formed by the first power line layer.

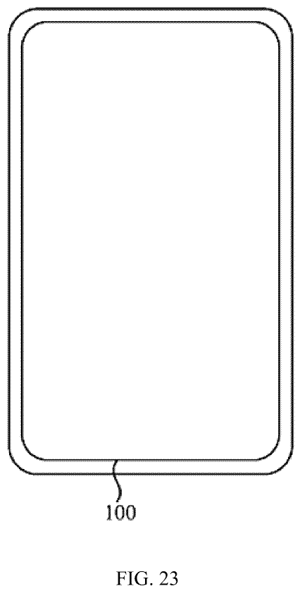

The present disclosure also provides a display device. The display device may include any display panel provided by various embodiments of the present disclosure. FIG. 23 is a structural schematic diagram of a display device provided by the embodiments of the present disclosure. As shown in FIG. 23, in one embodiment, the display device may include a display panel 100 provided by any of the above embodiments of the present disclosure. The embodiment of FIG. 23 only takes a mobile phone as an example to illustrate the display device. It may be understood that the display device provided by the embodiments of the present disclosure may also be a wearable product, a computer, a television, a car display device, or other display devices with display functions, and the present disclosure does not make specific restrictions on this. The display device provided in the embodiments of the present disclosure may have the beneficial effects of the display panel provided in the embodiments of the present disclosure. For details, references may be made to the specific description of the display panel in the above embodiments, which will not be repeated in this embodiment.

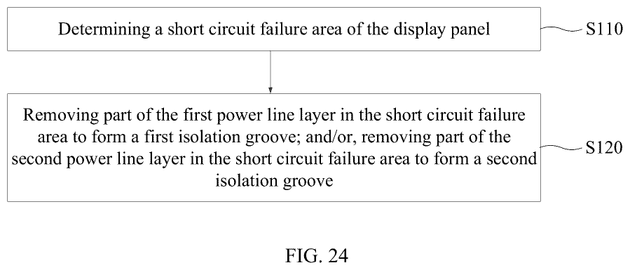

The present disclosure also provides a signal line repair method for a display panel. FIG. 24 is a flow chart of a signal line repair method for a display panel provided by the embodiments of the present disclosure. As shown in FIG. 24, in one embodiment, the signal line repair method for a display panel may include:
S110, determining a short circuit failure area of the display panel; and
S120, removing part of the first power line layer in the short circuit failure area to form a first isolation groove; and/or, removing part of the second power line layer in the short circuit failure area to form a second isolation groove.

The first power line layer may be located between the second power line layer and a substrate, and the first power line layer and the second power line layer may be insulated and overlapped. The first isolation groove may insulate a portion of the first power line layer in the short circuit failure area and another portion of the first power line layer in the non-short circuit failure area; and the second isolation groove may insulate a portion of the second power line layer in the short circuit failure area and another portion of the second power line layer in the non-short circuit failure area.

Because of the influence of foreign objects and external forces during the preparation and transportation process, an insulating film layer between the first power line layer 20 and the second power line layer 30 may easily broken, such that the first power line layer 20 and the second power line layer 30 may be deformed and conductive, thereby causing a short circuit problem. Therefore, in the embodiment of the present disclosure, the signal line repair method for the short circuit problem caused by the first power line layer 20 and the second power line layer 30 may be provided. First, the short circuit failure area of the display panel may be determined. The short circuit failure area may be an area where the normal power signal cannot be provided to the display panel because of the short circuit between the first power line layer and the second power line layer. The non-short circuit failure area may be an area that can provide the normal power signal to the display panel. Then, part of the first power line layer in the short circuit failure area may be removed to form the first isolation groove; and/or, part of the second power line layer in the short circuit failure area may be removed to form a second isolation groove. The first isolation groove may insulate a portion of the first power line layer in the short circuit failure area and another portion of the first power line layer in the non-short circuit failure area. Since the other portion of the first power line layer in the non-short circuit failure area is no longer connected to the portion of the first power line layer in the short circuit failure area, the abnormal signal received by the portion of the first power line layer in the short circuit failure area because of the short circuit may no longer be transmitted to the other portion of the first power line layer in the non-short circuit failure area. Therefore, the other portion of the first power line layer in the non-short circuit failure area may be able to guarantee a normal power signal. The second isolation groove may insulate a portion of the second power line layer in the short circuit failure area and another portion of the second power line layer in the non-short circuit failure area. Since the other portion of the second power line layer in the non-short circuit failure area is no longer connected to the portion of the second power line layer in the short circuit failure area, the abnormal signal received by the portion of the second power line layer in the short circuit failure area because of the short circuit may no longer be transmitted to the other portion of the second power line layer in the non-short circuit failure area. Therefore, the other portion of the second power line layer in the non-short circuit failure area may be able to guarantee a normal power signal.

In some embodiments, determining the short-circuit failure area of the display panel may include:
determining a short-circuit point of the display panel; and
using a position of the short-circuit point as the short-circuit failure area of the display panel.

Correspondingly, removing the part of the first power line layer in the short-circuit failure area to form the first isolation groove, and/or, removing the part of the second power line layer in the short-circuit failure area to form the second isolation groove, may include: removing part of the first power line layer at the short-circuit point to form the first isolation groove, and/or, removing part of the second power line layer at the short-circuit point to form the second isolation groove.

The short-circuit point of the short-circuit failure area may be a position where the first power line layer and the second power line layer are short-circuited. In one embodiment of the present disclosure, the short-circuit metal may be accurately removed at the short-circuit point for repair. For example, the short-circuit point of the display panel may be determined, and the location of the short-circuit point may be used as the short-circuit failure area of the display panel. Then, the part of the first power line layer at the short-circuit point may be removed to form the first isolation groove; and/or, the part of the second power line layer at the short-circuit point may be removed to form the second isolation groove. In the present application, when repairing at the short-circuit point, the formed short-circuit failure area may be small, which may reduce the area of bad pixels in the display panel.

In some other embodiments, determining the short-circuit failure area of the display panel may include:
determining the short-circuit point of the display panel; and
using the short-circuit point and an area within a preset distance outside the short-circuit point as the short-circuit failure area of the display panel.

Correspondingly, removing the part of the first power line layer in the short-circuit failure area to form the first isolation groove; and/or, removing the part of the second power line layer in the short-circuit failure area to form the second isolation groove, may include:
removing part of the first power line layer outside the short-circuit point to form the first isolation groove surrounding the short-circuit point; and/or, removing part of the second power line layer outside the short-circuit point to form the second isolation groove surrounding the short-circuit point.

In the present disclosure, the first isolation groove and/or the second isolation groove may be set to isolate around the short-circuit point, without directly repairing the short-circuit point. By setting the first isolation groove and/or the second isolation groove in an annular shape in the short-circuit failure area, the portion of the first power line layer in the short-circuit failure area and the other portion of the first power line layer in the non-short-circuit failure area may be insulated through the structure of the first isolation groove in an annular shape, and the portion of the second power line layer in the short-circuit failure area and the other portion of the second power line layer in the non-short-circuit failure area may be insulated by using the structure of the second isolation groove in an annular shape.

In some other embodiments, determining the short-circuit point of the display panel may include:
providing a test signal to the first power line layer and the second power line layer of the display panel; and
acquiring a thermal imaging image of the display panel, and determining the short-circuit point of the display panel based on the thermal imaging image.

In one embodiment of the present disclosure, the short-circuit point of the display panel may be determined by thermal imaging. After accurately determining the short-circuit point, the position of the first isolation groove and/or the second isolation groove may be accurately determined. For example, the test signal may be provided to the first power line layer and the second power line layer of the display panel. Since the short-circuit point position generates more heat than other non-short-circuit point positions after the test signal is passed, the short-circuit point of the display panel may be determined by acquiring a thermal imaging image of the display panel.

In some embodiments, removing the part of the first power line layer in the short circuit failure area to form the first isolation groove; and/or removing the part of the second power line layer in the short circuit failure area to form the second isolation groove may include:
using any one of capacitive coupling, laser etching, chemical etching, ion beam etching, or mechanical scraping processes to remove the part of the first power line layer in the short circuit failure area to form the first isolation groove; and/or to remove the part of the second power line layer in the short circuit failure area to form the second isolation groove.

In the embodiments of the present disclosure, any one of capacitive coupling, laser etching, chemical etching, ion beam etching, or mechanical scraping processes, may be used to form the first isolation groove and/or the second isolation groove. In practical applications, a suitable process may be selected according to the specific structural requirements, repair accuracy requirements, cost, and efficiency of the display panel.

In some embodiments, the second power line layer may be bonded to a light-emitting element through a bonding layer.

Removing the part of the first power line layer in the short circuit failure area to form the first isolation groove; and/or removing the part of the second power line layer in the short circuit failure area to form the second isolation groove may include:
on a side of the second power line layer away from the substrate, using laser etching to remove the part of the first power line layer in the short-circuit failure area to form the first isolation groove; and/or removing the part of the second power line layer in the short-circuit failure area to form the second isolation groove.

In the embodiment of the present disclosure, the second power line layer may be the metal layer of the light-emitting element closest to the display panel except the bonding layer. Therefore, when laser etching is used to form the first isolation groove and/or the second isolation groove, laser irradiation may be performed on the side of the second power line layer away from the substrate to avoid penetrating other metal film layers during laser irradiation.

In some other embodiments, removing the part of the first power line layer in the short circuit failure area to form the first isolation groove may include: controlling the laser to focus on the first power line layer to be etched to remove the part of the first power line layer in the short circuit failure area to form the first isolation groove.

And/or, removing the part of the second power line layer in the short circuit failure area to form the second isolation groove may include: controlling the laser to focus on the second power line layer to be etched to remove the part of the second power line layer in the short circuit failure area to form the second isolation groove.

In the embodiment of the present disclosure, when forming the first isolation groove and/or the second isolation groove by laser etching process, the laser focus position may be controlled, such that the film layer to be removed may be accurately etched during the laser etching process without damaging other film layers. Further, the laser energy may be adjusted to ensure that the metal to be etched absorbs enough energy to be vaporized. For example, when the part of the first power line layer in the short circuit failure area needs to be removed to form the first isolation groove, the laser may be controlled to focus on the first power line layer to be etched to remove the part of the first power line layer in the short circuit failure area to form the first isolation groove. For example, when the part of the second power line layer in the short circuit failure area needs to be removed to form a second isolation groove, the laser may be controlled to focus on the second power line layer to be etched to remove part of the second power line layer in the short circuit failure area to form the second isolation groove.

In the embodiments of the present disclosure, the parameters of the laser etching process, such as the focal length of the optical system, the laser energy, etc., may be adjusted according to the film layer to be etched and the etching depth.

In the present disclosure, relational terms such as “first” and “second” are only used to distinguish one entity or operation from another entity or operation, and do not necessarily require or imply that there is a relationship between these entities or operations. There is no such actual relationship or sequence. Furthermore, the terms “comprises”, “include”, or any other variations thereof are intended to cover a non-exclusive inclusion such that a process, method, article, or apparatus that includes a list of elements includes not only those elements, but also those not expressly listed, or elements inherent to the process, method, article or equipment. Without further limitation, an element defined by the statement “comprises a . . . ” does not exclude the presence of additional identical elements in a process, method, article, or apparatus that includes the stated element.

Various embodiments have been described to illustrate the operation principles and exemplary implementations. It should be understood by those skilled in the art that the present disclosure is not limited to the specific embodiments described herein and that various other obvious changes, rearrangements, and substitutions will occur to those skilled in the art without departing from the scope of the disclosure. Thus, while the present disclosure has been described in detail with reference to the above described embodiments, the present disclosure is not limited to the above described embodiments, but may be embodied in other equivalent forms without departing from the scope of the present disclosure, which is determined by the appended claims.

What is claimed is:

1. A display panel, comprising:
a substrate; and
a first power line layer and a second power line layer located on the substrate,
wherein:
the first power line layer is located between the second power line layer and the substrate;
the first power line layer and the second power line layer are insulated and overlap each other;
the display panel has a short-circuit failure area and a non-short-circuit failure area, and the short-circuit failure area is provided with at least one of a first isolation groove or a second isolation groove;
the first isolation groove insulates a portion of the first power line layer in the short-circuit failure area from another portion of the first power line layer in the non-short-circuit failure area; and
the second isolation groove insulates a portion of the second power line layer in the short-circuit failure area from another portion of the second power line layer in the non-short-circuit failure area.

2. The display panel according to claim 1, wherein:
in a direction perpendicular to a plane where the display panel is located, the first isolation groove at least penetrates the first power line layer; and
in the direction perpendicular to the plane where the display panel is located, the second isolation groove at least penetrates the second power line layer.

3. The display panel according to claim 1, wherein:
in a direction perpendicular to the substrate, the first isolation groove extends to at least a portion of an insulating layer between the first power line layer and the second power line layer; and/or,
in the direction perpendicular to the substrate, the second isolation groove extends to at least a portion of the insulating layer between the first power line layer and the second power line layer.

4. The display panel according to claim 1, wherein:
the short circuit failure area is provided with the first isolation groove, and an insulating layer is provided between the first isolation groove and the second power line layer; or
the short circuit failure area is provided with the second isolation groove, and an insulating layer is provided between the first isolation groove and the first power line layer.

5. The display panel according to claim 1, wherein:
in a direction perpendicular to the substrate, metal layers between the first power line layer and the substrate do not overlap with the first isolation groove and/or the second isolation groove.

6. The display panel according to claim 1, wherein:
the first isolation groove and/or the second isolation groove are located at a short-circuit point of the short-circuit failure area.

7. The display panel according to claim 6, wherein:
a vertical projection of the short-circuit point on the substrate is located within a vertical projection of the first isolation groove on the substrate; and/or
a vertical projection of the short-circuit point on the substrate is located within a vertical projection of the second isolation groove on the substrate; and/or
an area of the short-circuit point is less than or equal to a laser etching spot area of the first isolation groove and the second isolation groove.

8. The display panel according to claim 1, wherein:
the first isolation groove and/or the second isolation groove are arranged in a ring shape in the short-circuit failure area.

9. The display panel according to claim 8, wherein:
the short-circuit failure area includes a short-circuit point, and the first isolation groove and/or the second isolation groove are arranged around the short-circuit point; and
a maximum width of the short-circuit point is larger than a width of the first isolation groove and/or the second isolation groove.

10. The display panel according to claim 9, wherein:
in a direction parallel to a plane of the substrate, a ratio of the distance between the first isolation groove and/or the second isolation groove and the short-circuit point to a size of a light-emitting element arrangement area along a first direction is less than 1, wherein the distance between the first isolation groove and/or the second isolation groove and the short-circuit point is parallel to the first direction.

11. The display panel according to claim 8, wherein:
the second power line layer includes a first electrode portion and a second electrode portion electrically insulated;
in a light-emitting element arrangement area, the first electrode portion is used to be electrically connected to an anode of the light-emitting element, and the second electrode portion is used to be electrically connected to a cathode of the light-emitting element; and
in a direction perpendicular to the substrate, the second isolation groove does not overlap with the first electrode portion and/or the second electrode portion in the light-emitting element arrangement area.

12. The display panel according to claim 8, wherein:
the second power line layer includes a first electrode portion and a second electrode portion electrically insulated;
in a light-emitting element arrangement area, the first electrode portion is used to be electrically connected to an anode of the light-emitting element, and the second electrode portion is used to be electrically connected to a cathode of the light-emitting element; and
in a direction perpendicular to the substrate, the first isolation groove overlaps with the first electrode portion and/or the second electrode portion in the light-emitting element arrangement area.

13. The display panel according to claim 8, wherein:
the first power line layer is provided with a plurality of first exhaust holes, and the first isolation groove is connected to at least part of the plurality of first exhaust holes; and/or
the second power line layer is provided with a plurality of second exhaust holes, and the second isolation groove is connected to at least part of the plurality of second exhaust holes.

14. A display device, comprising a display panel, wherein:
the display panel includes: a substrate, and a first power line layer and a second power line layer located on the substrate,
wherein:
the first power line layer is located between the second power line layer and the substrate;
the first power line layer and the second power line layer are insulated and overlapped;
the display panel has a short-circuit failure area and a non-short-circuit failure area, and the short-circuit failure area is provided with a first isolation groove and/or a second isolation groove;
the first isolation groove insulates a portion of the first power line layer in the short-circuit failure area from another portion of the first power line layer in the non-short-circuit failure area; and
the second isolation groove insulates a portion of the second power line layer in the short-circuit failure area from another portion of the second power line layer in the non-short-circuit failure area.

15. A signal line repairing method of a display panel, comprising:
determining a short circuit failure area of the display panel; and
removing part of the first power line layer in the short circuit failure area to form a first isolation groove; and/or, removing part of the second power line layer in the short circuit failure area to form a second isolation groove,
wherein:
the first power line layer is located between the second power line layer and a substrate;
the first power line layer and the second power line layer are insulated and overlapped;
the first isolation groove insulates a portion of the first power line layer in the short circuit failure area and another portion of the first power line layer in the non-short circuit failure area; and
the second isolation groove insulates a portion of the second power line layer in the short circuit failure area and another portion of the second power line layer in the non-short circuit failure area.

16. The method according to claim 15, wherein:
determining the short-circuit failure area of the display panel includes:
determining a short-circuit point of the display panel; and
using a position of the short-circuit point as the short-circuit failure area of the display panel, and
removing the part of the first power line layer in the short-circuit failure area to form the first isolation groove, and/or, removing the part of the second power line layer in the short-circuit failure area to form the second isolation groove, include:
removing a portion of the first power line layer at the short-circuit point to form the first isolation groove; and/or, removing a portion of the second power line layer at the short-circuit point to form the second isolation groove.

17. The method according to claim 15, wherein:
determining the short-circuit failure area of the display panel includes:
determining a short-circuit point of the display panel;
using the short-circuit point and an area within a preset distance around the short-circuit point as the short-circuit failure area of the display panel, and
removing the part of the first power line layer in the short-circuit failure area to form the first isolation groove, and/or, removing the part of the second power line layer in the short-circuit failure area to form the second isolation groove, include:
removing part of the first power line layer around the short-circuit point in the short-circuit failure area to form the first isolation groove surrounding the short-circuit point; and/or, removing part of the second power line layer around the short-circuit point in the short-circuit failure area to form the second isolation groove surrounding the short-circuit point.

18. The method according to claim 15, wherein:
removing the part of the first power line layer in the short-circuit failure area to form the first isolation groove, and/or, removing the part of the second power line layer in the short-circuit failure area to form the second isolation groove, include:
using any one of capacitive coupling, laser etching, chemical etching, ion beam etching, or mechanical scraping processes to remove the part of the first power line layer in the short circuit failure area to form the first isolation groove and/or remove the part of the second power line layer in the short circuit failure area to form the second isolation groove.

19. The method according to claim 18, wherein:
the second power line layer is bonded with a light emitting element through a bonding layer; and
removing the part of the first power line layer in the short-circuit failure area to form the first isolation groove, and/or, removing the part of the second power line layer in the short-circuit failure area to form the second isolation groove, include:
on a side of the second power line layer away from the substrate, using laser etching to remove the part of the first power line layer in the short circuit failure area to form the first isolation groove and/or remove the part of the second power line layer in the short circuit failure area to form the second isolation groove.

20. The method according to claim 15, wherein:
removing the part of the first power line layer in the short-circuit failure area to form the first isolation groove includes controlling laser to focus on the first power line layer to be etched to remove the part of the first power line layer in the short circuit failure area and form the first isolation groove; and/or
removing the part of the second power line layer in the short-circuit failure area to form the second isolation groove includes controlling laser to focus on the second power line layer to be etched to remove the part of the second power line layer in the short circuit failure area and form the second isolation groove.
